(19) United States
(12) Patent Application Publication
(10) Pub. No.: US 2023/0249500 A1
(43) Pub. Date: Aug. 10, 2023

(54) TIRE PRESSURE MONITORING SYSTEM

(71) Applicant: Sensata Technologies, Inc., Attleboro, MA (US)

(72) Inventor: Gary Smith, Wootton Bassett, Wiltshire (GB)

(21) Appl. No.: 18/003,069

(22) PCT Filed: Jun. 30, 2020
(86) PCT No.: PCT/US2020/040337

§ 371 Date: Dec. 22, 2022

(51) Int. Cl. B60C 23/04; H03G 3/30

(52) U.S. Cl. CPC B60C 23/045; H03G 3/30; B60C 23/0461; H03G 2201/103

(57) ABSTRACT

The present disclosure relates to a system and method for a tire pressure monitoring system. Embodiments may include a first amplifier associated with a plurality of amplifiers that is configured to receive a signal. The plurality of amplifiers may be configured to generate a first output, wherein generating includes filtering the signal and increasing an amplitude of the signal. A fixed threshold comparator may be configured to receive the first output and to generate a second output, based upon, at least in part, the first output, wherein the second output has the same frequency as the signal. Automatic gain control logic may be configured to receive the second output and determine a number of cycles in a given time period, the automatic gain control logic may be further configured to determine whether a revision to a setting of the automatic gain control logic is necessary.

### TECHNICAL FIELD

The present disclosure generally applies to monitoring systems, more specifically a system and method for a tire pressure monitoring system.

### BACKGROUND

Tire pressure monitoring systems (“TPMS”) are electrical systems designed to monitor the air pressure inside the tires of vehicles. These systems generally operate in real-time periodically measuring tire pressure to help avoid traffic accidents, poor fuel economy, and improve wear on the tires. Numerous countries around the world mandate these systems in vehicles because of their effectiveness in creating a safer driving environment.

A TPMS is generally located inside the tire without direct electrical power. Therefore, any TPMS may need to be battery operated. When a battery dies the vehicle operator typically needs to undergo a time-consuming process of removing the wheel and the tire to access the TPMS. In commercial vehicles this can mean a direct loss of money while the TPMS is fully replaced or the battery is replaced. There is a continual need in the TPMS market for increasing the life of the system to reduce down time and increase the effectiveness of this important safety system.

A TPMS may require a low frequency (“LF”) channel to be polled periodically (typically every second) for the ten year life of the part. Each poll will require current, and thus over the lifetime of the TPMS, it will have a significant impact on the battery life of the system.

### SUMMARY OF THE DISCLOSURE

As will be discussed in greater detail below, embodiments of the present disclosure include a tire pressure monitoring system.

In one or more embodiments of the present disclosure, a method associated with a tire pressure monitoring system (“TPMS”) is included. The method may include receiving a signal at a first amplifier associated with a plurality of amplifiers. The method may also include, generating a first output at the plurality of amplifiers, wherein generating includes filtering the signal and increasing an amplitude of the signal. The method may further include receiving the first output at a fixed threshold comparator and generating a second output, based upon, at least in part, the first output, at the fixed threshold comparator, wherein the second output has the same frequency as the signal. The method may also include receiving the second output at automatic gain control logic and determining, at the automatic gain control logic, a number of cycles in a given time period. The method may further include determining whether a revision to a setting of the automatic gain control logic is necessary.

One or more of the following features may be included. In some embodiments, the second output may be a square wave. If a revision is necessary, the method may include determining a revised AGC setting. The method may further include interrogating the automatic gain control logic to locate one or more gain settings produced by the automatic gain control logic. In some embodiments, the plurality of amplifiers may be two amplifiers and the signal may be a 125 kHz signal. Generating the second output may occur if the first output exceeds a comparator threshold. The method may also include monitoring a low frequency channel for a first time period and turning off the plurality of amplifiers for a second time period that is longer than the first time period. The automatic gain control logic may be only activated after detection of an initial signal.

In one or more embodiments of the present disclosure, a TPMS system is provided. The system may include a first amplifier associated with a plurality of amplifiers that is configured to receive a signal. The plurality of amplifiers may be configured to generate a first output, wherein generating includes filtering the signal and increasing an amplitude of the signal. A fixed threshold comparator may be configured to receive the first output and to generate a second output, based upon, at least in part, the first output, wherein the second output may have the same frequency as the signal. Automatic gain control logic may be configured to receive the second output and determine a number of cycles in a given time period. The automatic gain control logic may be further configured to determine whether a revision to a setting of the automatic gain control logic is necessary.

One or more of the following features may be included. In some embodiments the second output may be a square wave. If a revision is necessary, the automatic gain control logic may be configured to determine a revised AGC setting. The automatic gain control logic may also be interrogated to locate one or more gain settings produced by the automatic gain control logic. In some embodiments, the plurality of amplifiers may be two amplifiers and the signal may be a 125 kHz signal. Generating the second output may occurs if the first output exceeds a comparator threshold. A low frequency channel may be monitored for a first time period and the plurality of amplifiers may be turned off for a second time period that is longer than the first time period. The automatic gain control logic may be only activated after detection of an initial signal.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

This summary is provided to introduce a selection of concepts that are further described below in the detailed description. This summary is not intended to identify essential features of the claimed subject matter, nor is it intended to be used as an aid in limiting the scope of the claimed subject matter.

### BRIEF DESCRIPTION OF THE DRAWINGS

The accompanying drawings, which are included to provide a further understanding of embodiments of the present disclosure and are incorporated in and constitute a part of this specification, illustrate embodiments of the present disclosure and together with the description serve to explain the principles of embodiments of the present disclosure.

FIG. 1 illustrates a block diagram of an embodiment of the present disclosure;

FIG. 2 illustrates an embodiment with a sniff and digital automatic gain control cycle;

FIG. 3 illustrates the gain provided by the automatic gain control compared to signal strength;

FIG. 4 illustrates a chart showing a low frequency tire pressure monitoring system output voltage and input voltage;

FIG. 5 illustrates the advantages of a digital automatic gain control compared to an analog automatic gain control; and

FIG. 6 illustrates a flowchart consistent with embodiments of the tire pressure monitoring system.

Like reference symbols in the various drawings may indicate like elements.

### DETAILED DESCRIPTION

The discussion below is directed to certain implementations. It is to be understood that the discussion below is only for the purpose of enabling a person with ordinary skill in the art to make and use any subject matter defined now or later by the patent “claims” found in any issued patent herein.

It is specifically intended that the claimed combinations of features not be limited to the implementations and illustrations contained herein, but include modified forms of those implementations including portions of the implementations and combinations of elements of different implementations as come within the scope of the following claims. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the claimed invention unless explicitly indicated as being “critical” or “essential.”

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the invention. The first object or step, and the second object or step, are both objects or steps, respectively, but they are not to be considered a same object or step.

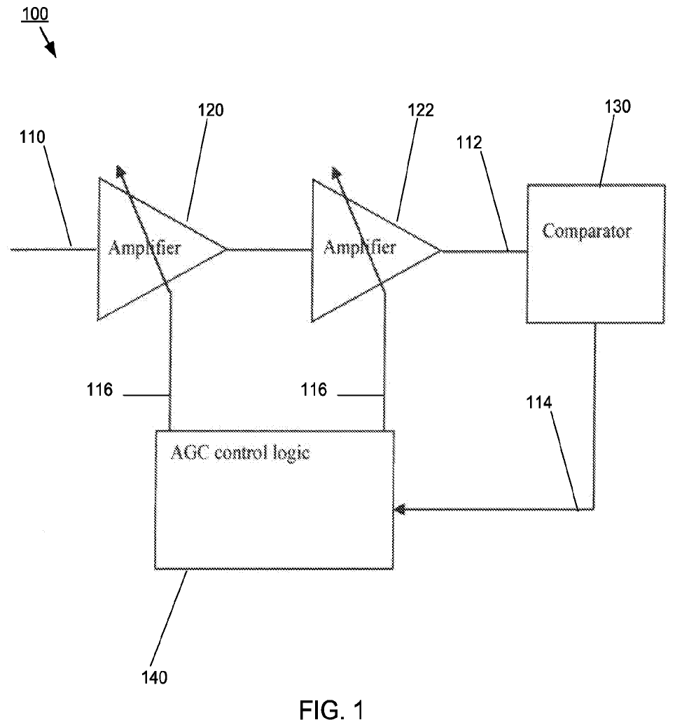

Referring now to FIG. 1, an embodiment consistent with the present disclosure showing a tire pressure monitoring system (“TPMS”) 100 is provided. TPMS 100 may include, an input signal 110, a first amplifier 120, a second amplifier 122, a first output signal 112, a comparator 130, a second output signal 114, an automatic gain control (“AGC”) logic 140, and an AGC logic output signal 116. TPMS 100 represents one possible arrangement of the interconnectedness of these components though it should be noted that other arrangements are also within the scope of the present disclosure.

In some embodiments, the input signal 110 may have a low frequency, for example, a 10 Hz signal. The term “low frequency”, as used herein, may refer to any frequencies within a range of 1-50 Hz. In other embodiments, the input signal 110 may be monitored for specified time period and/or in a continuous manner.

In some embodiments, input signal 110 may be received at a plurality of amplifiers, for example, first amplifier 120 and second amplifier 122. Any number of amplifiers may be used without departing from the scope of the present disclosure. The plurality of amplifiers may be configured in a chain, and the amplifier chain may have a variable gain.

In some embodiments, first amplifier 120 and the second amplifier 122 may be configured to filter the input signal 110 and increase the amplitude of the input signal 110 resulting in the first output signal 112. In some embodiments, the first output signal 112 may have the same frequency as the input signal (in this example 125 kHz). In some embodiments, the first amplifier 120 and the second amplifier 122 may not operate continuously. In other embodiments, the first amplifier 120 and the second amplifier 122 may be turned off for a time longer than the input signal 110 is being monitored.

In some embodiments, and as shown in FIG. 1, first output signal 112 may be fed into comparator 130. Comparator 130 may be a fixed threshold comparator though any suitable comparator may be employed without departing from the teachings of the present disclosure. Comparator 130 may generate second output signal 114, which may have the same frequency as the input signal 110 if the first output signal 112 exceeds a threshold associated with comparator 130. Second output signal 114 may have a frequency of 125 kHz and may be configured as a square wave.

In some embodiments, AGC logic 140 may be configured to receive second output signal 114 from comparator 130. In operation, AGC logic 140 may count the number of specified frequency cycles in a given time period. For example, the AGC logic may count the number of 125 kHz cycles in a given time period. Based on the count of the frequency cycles, AGC logic 140 may determine and/or adjust a setting configuration of the AGC logic 140. In other embodiments, TPMS 100 (specifically AGC logic 140) may wait for a specified number of frequency cycles to occur then count the time period that has elapsed.

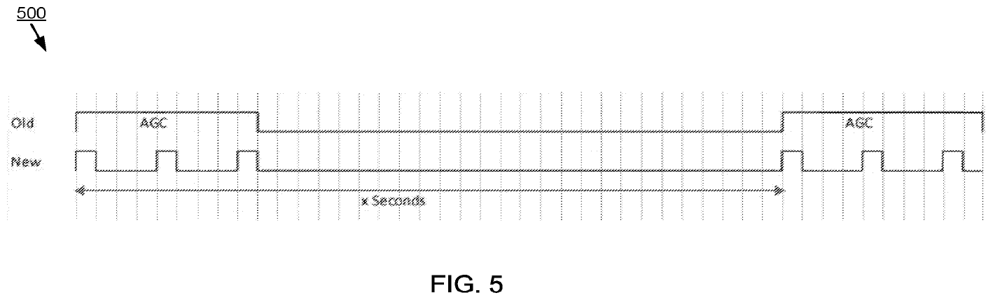

In some embodiments, AGC logic 140 may not operate continuously. For example, in some cases, AGC logic 140 may operate periodically. In other embodiments, the AGC logic 140 may be activated only when there is a detection of input signal 110. For example, where AGC logic 140 is activated only after the detection of input signal 110, TPMS 100 may operate faster than a typical TPMS. Accordingly, using the teachings of the present disclosure, greater than 80% of the energy required to perform the low frequency operation may be reduced as compared to a typical TPMS. This is discussed in further detail below, and more particularly with reference to FIG. 5.

In some embodiments, AGC logic 140 may be configured to generate AGC logic output signal 116. AGC logic output signal 116 may alter the gain settings of the plurality of amplifiers, for example, first amplifier 120 and second amplifier 122. AGC logic 140 may then receive a different second output signal 114 from the altered gain settings and, once again, begin the count of the number of specified frequency cycles in a given time period.

In some embodiments, AGC control logic 140 may be interrogated to locate one or more gain settings produced by the AGC logic 140. Accordingly, when AGC control logic 140 is interrogated, input signal 110 level may be determined.

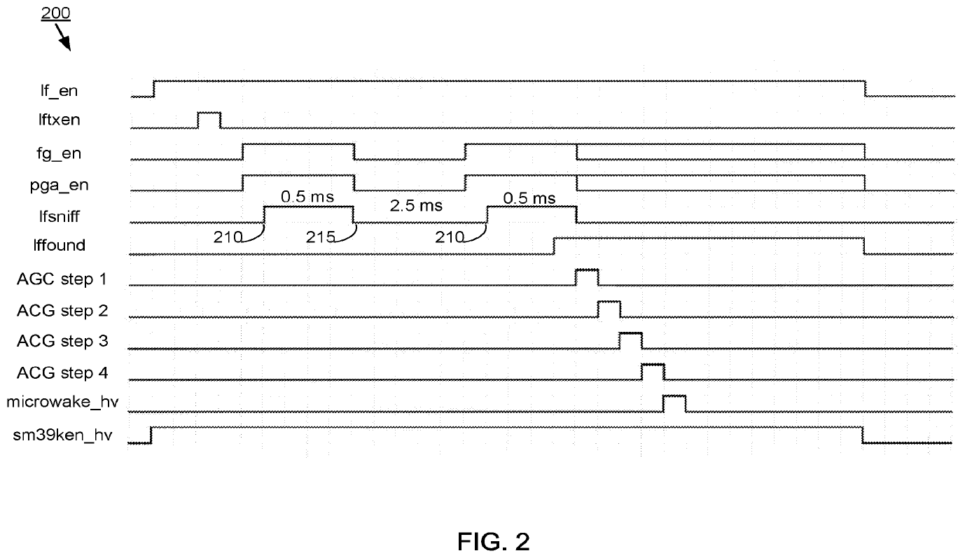

Referring now to FIG. 2, a Timing Diagram 200 consistent with a sniff and digital automatic gain control cycle is provided. Timing Diagram 200 illustrates the interactions between the signals for a typical sniff operation. The term “sniff”, as used herein, may refer to an operation wherein TPMS 100 periodically monitors for a signal. In some implementations, such as that shown in FIG. 2, the sniff may be looking for a signal in the low frequency channel.

Timing Diagram 200 shows an example period of enabling a low frequency sniff. For example, if signal lf_en registers a high value a low frequency channel may be activated to start sniffing. The labels on the signal chart 200 represent the following:

| Chart Label | Signal Meaning |
|---|---|
| lf_en | low frequency enabled |
| fg_en | first amplifier enabled |
| pga_en | second amplifier enabled |
| lfsniff | low frequency sniff enabled |
| lffound | low frequency preamble signal found |
| AGC Step 1-4 | Automatic gain control steps |
| microwake_hv | Wake and message the microcontroller |
| sm39ken_hv | System clock enabled |

As shown in FIG. 2, when signal fg_en and signal pga_en read high, the plurality of amplifiers may be enabled (e.g., first amplifier 120 and second amplifier 122 as discussed above with reference to FIG. 1). With the plurality of amplifiers engaged, there may be a maximum gain for the sniff. In some embodiments, when signal fg_en reads high a first amplifier may be enabled. Signal fg_en may be enabled for the sniff period and may be enabled by, for example, the AGC to improve reception. In some embodiments, like FIG. 2, when signal pga_en reads high a second amplifier may be enabled. Signal fg_en may be enabled for the sniff period and may be enabled by, for example, the AGC to improve reception.

In some embodiments, signal lfsniff may be enabled for a first time period 210. In some embodiments, the first time period 210 may be 0.5 milliseconds. When signal lfsniff is high the system (e.g. TPMS 100) may be checking for a minimum number of counts of a specified frequency cycle in a given time. If no low frequency signal is measured, then the amplifiers and/or the system (e.g. TPMS 100) may turn off. In some embodiments, if no low frequency signal is measured, then the amplifiers and/or the system may be suspended until the next sniff period. In some embodiments, the low frequency signal may have a frequency of 125 kHz. The sniffer may also turn off for a second time period 215. In some embodiments, the second time period 215 may be longer than the first time period 210 as shown in FIG. 2, to save additional power. In other embodiments, the first time period 210 and the second time period 215 may be the same length of time. In further embodiments, the first time period 210 may be longer than the second time period 215. In other embodiments, the second time period 215 may be 2.5 milliseconds. The length of the first time period 210 and the second time period 215 are structured in order to catch the low frequency preamble signal. In some embodiments, the preamble signal may be 5 milliseconds. It should be noted that the examples included herein showing 0.5 milliseconds, 2.5 milliseconds, etc. are provided merely by way of example and to illustrate the concepts included herein.

In some embodiments, if signal lfsniff finds the required count of frequency cycles in the preamble signal, then signal lffound may be enabled and thus be high. When signal lffound is low after the sniff, then the count of frequency cycles in the preamble signal was not sufficient. In some embodiments, a system clock may be enabled by signal sm39ken_hv to perform the timing.

In some embodiments, when signal lffound is high then the AGC steps may initiate. For example, AGC Steps 1-4 may depict a four step binary search. In some embodiments like in FIG. 2 this may correspond to 16 gain settings. The AGC steps may determine what amplifiers to enable and what gain to use for best reception. In other embodiments, a different number of steps and different number of gain settings may also be utilized. When signal lffound is high and AGC Step 1-4 are initiated the amplifiers may remain on or may be turned on as needed by the AGC. Each of the AGC steps may run for a set period of time. In some embodiments, each AGC step may run for 0.5 milliseconds. In other embodiments, the total of the four AGC steps may run for 2 milliseconds. In some embodiments, when the AGC has completed the binary search, signal microwake_hv may be high. When signal microwake_hv is high, a microcontroller may be engaged and receive a message that the ACG has completed the binary search and/or completed other functions the ACG is performing.

In some embodiments, the duration of the ON and OFF cycle in the first time period 210 and the second time period 215, respectively, may be configured to ensure the AGC steps end at the same time or before the preamble signal ends. For example, if the preamble signal lffound is 5 milliseconds, as in some embodiments, then in a worst case scenario where the plurality of amplifiers are OFF for a full 2.5 milliseconds of the preamble signal, a 0.5 millisecond sniff may still locate the preamble signal and run the AGC steps before the preamble signal ends.

In some embodiments, the value of the AGC steps may be fixed for the duration of signal lf_en and therefore the gain value may indicate a received signal strength indication (“RSSI”). In some embodiments, that may include using the gain value from the AGC, and, as such, the RSSI may be included in the TPMS without requiring extra circuitry to further save energy and space within the TPMS.

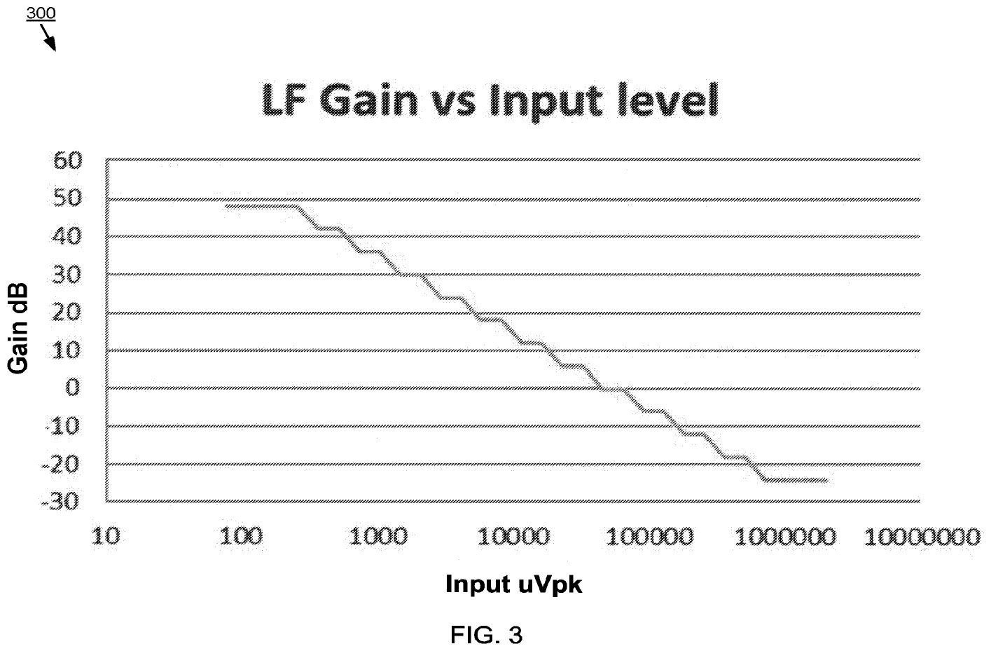

Referring now to FIG. 3, a chart 300 showing the gain provided by the AGC compared to signal strength is provided. Specifically, FIG. 3 shows gain versus the input level for an embodiment similar to FIG. 2. The lower the input signal strength the more gain the AGC may provide to the signal and, conversely, if the input signal strength is large the AGC may reduce the strength of the signal. In some embodiments, the AGC may adjust the strength of the input signal without the use of the amplifiers, for example, in situations where the input level is large. By using the gain from the AGC steps the input level may be accurately determined. In some embodiments, the input level may be determined to within 6 dB. However, in other embodiments, the accuracy of the input level may be adjusted as needed.

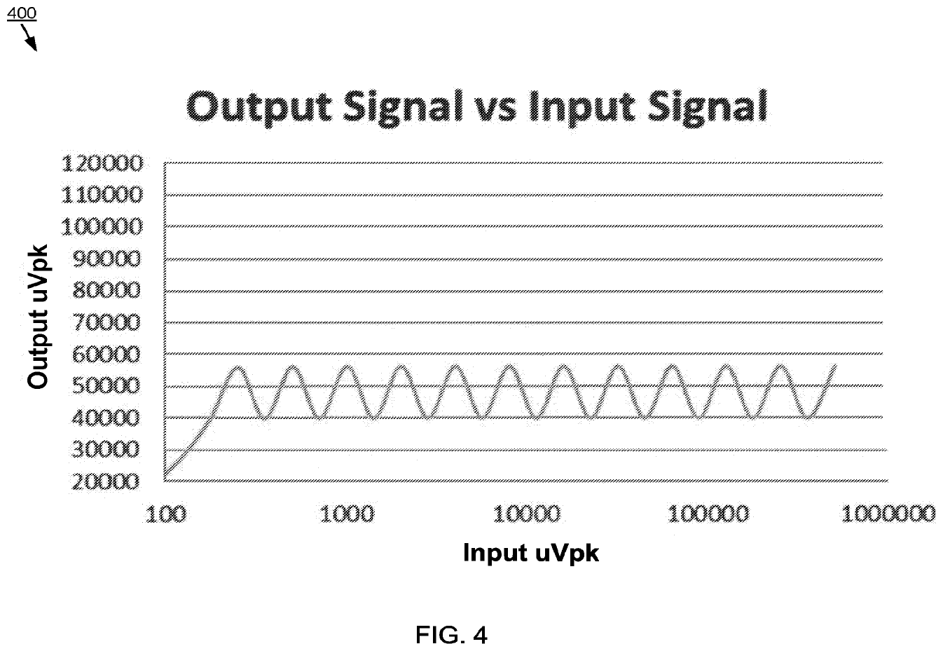

Referring now to FIG. 4, a chart 400 showing output signal voltage versus input signal voltage for the different AGC settings is provided. In some embodiments, the output voltage may be constrained within limits over the operating range voltages. In some embodiments, the comparator may have a fixed comparison threshold.

Embodiments of the present disclosure remove the need for additional components such as a data slicers, which may not be necessary when using the teachings of the present disclosure. There are significant energy savings that can occur from using duty cycling, similar to that described in FIG. 2. For example ⅙ of the energy may be required in embodiments that use a 0.5 millisecond sniff and 2.5 millisecond off period as compared to an analog system that cannot duty cycle. Depending on the gain setting the AGC uses, the AGC may disable the gain blocks that are not required from operation, further increasing energy savings.

Referring now to FIG. 5, a signal chart 500 showing the aforementioned energy saving advantage of duty cycling consistent with embodiments of the present disclosure is provided. Old, analog TPMS arrangements do not cycle the power due to circuit limitations and must remain on for a certain period of time looking for the low frequency signal. Accordingly, embodiments of the present disclosure are able to utilize a binary search for a faster and more power efficient low frequency sniff for a period of x seconds.

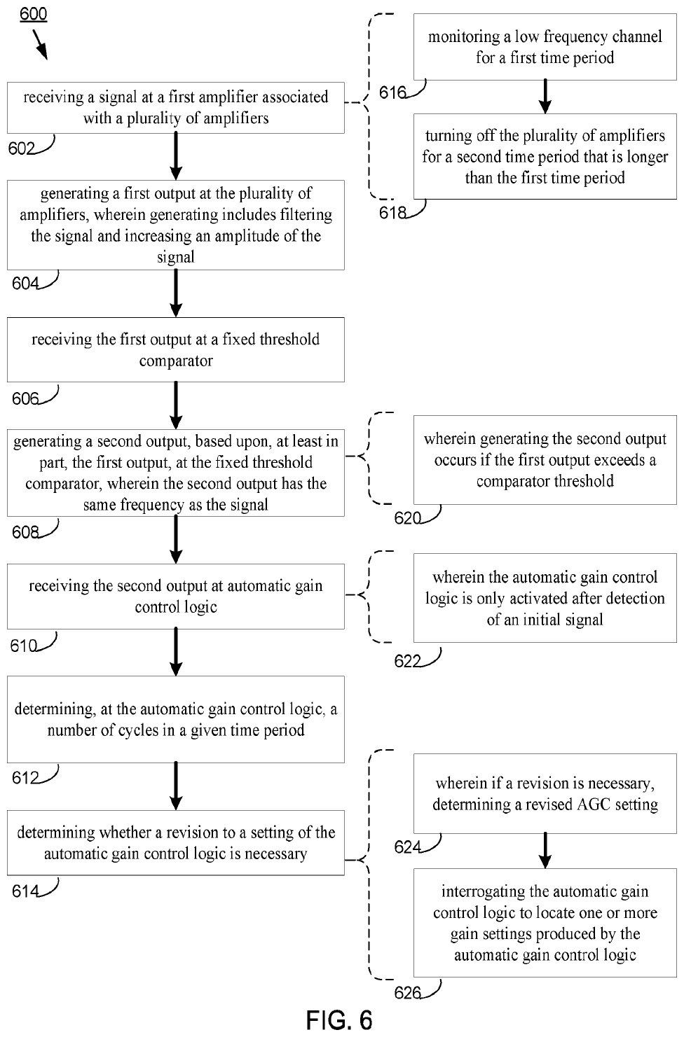

Referring now to FIG. 6, a flowchart 600 consistent with embodiments of TPMS 100 is provided. The method may include receiving (602) a signal at a first amplifier associated with a plurality of amplifiers and generating (604) a first output at the plurality of amplifiers, wherein generating includes filtering the signal and increasing an amplitude of the signal. The method may include receiving (606) the first output at a fixed threshold comparator and generating (608) a second output, based upon, at least in part, the first output, at the fixed threshold comparator, wherein the second output has the same frequency as the signal. The method may include (610) receiving the second output at automatic gain control logic and determining (612), at the automatic gain control logic, a number of cycles in a given time period. The method may further include determining (614) whether a revision to a setting of the automatic gain control logic is necessary.

In some embodiments, the method may further include monitoring (616) a low frequency channel for a first time period. The method may also include turning off (618) the plurality of amplifiers for a second time period that is longer than the first time period.

In some embodiments, the method may further include generating (608) a second output, based upon, at least in part, the first output, at the fixed threshold comparator, wherein the second output has the same frequency as the signal may further include, wherein generating the second output occurs if the first output exceeds a comparator threshold (620). In some embodiments, the method may include receiving (610) the second output at automatic gain control logic. The automatic gain control logic may only be activated after detection of an initial signal (622).

In some embodiments, the method may include determining (614) whether a revision to a setting of the automatic gain control logic is necessary. If a revision is necessary, the method may include determining a revised AGC setting (624). The method may also include interrogating (626) the automatic gain control logic to locate one or more gain settings produced by the automatic gain control logic

As used in any embodiment described herein, the term “circuitry” may comprise, for example, singly or in any combination, hardwired circuitry, programmable circuitry, state machine circuitry, and/or firmware that stores instructions executed by programmable circuitry. It should be understood at the outset that any of the operations and/or operative components described in any embodiment or embodiment herein may be implemented in software, firmware, hardwired circuitry and/or any combination thereof.

The terminology used herein is for the purpose of describing particular embodiments and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

Although a few example embodiments have been described in detail above, those skilled in the art will readily appreciate that many modifications are possible in the example embodiments without materially departing from the scope of the present disclosure, described herein. Accordingly, such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112, paragraph 6 for any limitations of any of the claims herein, except for those in which the claim expressly uses the words ‘means for’ together with an associated function.

Having thus described the disclosure of the present application in detail and by reference to embodiments thereof, it will be apparent that modifications and variations are possible without departing from the scope of the disclosure defined in the appended claims.

What is claimed is:

1. A method associated with a tire pressure monitoring system (“TPMS”), comprising:
receiving a signal at a first amplifier associated with a plurality of amplifiers;
generating a first output at the plurality of amplifiers, wherein generating includes filtering the signal and increasing an amplitude of the signal;
receiving the first output at a fixed threshold comparator;
generating a second output, based upon, at least in part, the first output, at the fixed threshold comparator, wherein the second output has the same frequency as the signal;
receiving the second output at automatic gain control logic;
determining, at the automatic gain control logic, a number of cycles in a given time period; and
determining whether a revision to a setting of the automatic gain control logic is necessary.

2. The method of claim 1, wherein the second output is a square wave.

3. The method of claim 1, wherein if a revision is necessary, determining a revised AGC setting.

4. The method of claim 3, further comprising:
interrogating the automatic gain control logic to locate one or more gain settings produced by the automatic gain control logic.

5. The method of claim 1, wherein the plurality of amplifiers is two amplifiers.

6. The method of claim 1, wherein the signal is a 125 kHz signal.

7. The method of claim 1, wherein generating the second output occurs if the first output exceeds a comparator threshold.

8. The method of claim 1, further comprising:
monitoring a low frequency channel for a first time period.

9. The method of claim 8, further comprising:
turning off the plurality of amplifiers for a second time period that is longer than the first time period.

10. The method of claim 1, wherein the automatic gain control logic is only activated after detection of an initial signal.

11. A TPMS system comprising:
a first amplifier associated with a plurality of amplifiers that is configured to receive a signal, wherein the plurality of amplifiers is configured to generate a first output, wherein generating includes filtering the signal and increasing an amplitude of the signal;
a fixed threshold comparator configured to receive the first output and to generate a second output, based upon, at least in part, the first output, wherein the second output has the same frequency as the signal; and
automatic gain control logic configured to receive the second output and determine a number of cycles in a given time period, the automatic gain control logic further configured to determine whether a revision to a setting of the automatic gain control logic is necessary.

12. The TPMS system of claim 11, wherein the second output is a square wave.

13. The TPMS system of claim 11, wherein if a revision is necessary, the automatic gain control logic is configured to determine a revised AGC setting.

14. The TPMS system of claim 13, wherein the automatic gain control logic is interrogated to locate one or more gain settings produced by the automatic gain control logic.

15. The TPMS system of claim 11, wherein the plurality of amplifiers is two amplifiers.

16. The TPMS system of claim 11, wherein the signal is a 125 kHz signal.

17. The TPMS system of claim 11, wherein generating the second output occurs if the first output exceeds a comparator threshold.

18. The TPMS system of claim 11, wherein a low frequency channel is monitored for a first time period.

19. The TPMS system of claim 18, wherein the plurality of amplifiers are turned off for a second time period that is longer than the first time period.

20. The TPMS system of claim 11, wherein the automatic gain control logic is only activated after detection of an initial signal.
